(19) United States
(12) Patent Application Publication
(10) Pub. No.: US 2024/0147870 A1
(43) Pub. Date: May 2, 2024

(54) METHOD FOR MANUFACTURING SUPERCONDUCTING FILMS, SUPERCONDUCTING FILM, QUANTUM DEVICE, AND QUANTUM CHIP

(71) Applicant: Alibaba Damo (Hangzhou) Technology Co., Ltd., Hangzhou (CN)

(72) Inventor: Make YING, Hangzhou (CN)

(21) Appl. No.: 18/482,351

(22) Filed: Oct. 6, 2023

(30) Foreign Application Priority Data
Oct. 27, 2022 (CN) 202211329048.8

(51) Int. Cl. H10N 60/01; G06N 10/40

(52) U.S. Cl. CPC H10N 60/0241; G06N 10/40; H10N 60/0716

(57) ABSTRACT

A method for manufacturing superconducting films. The method includes: heating a first atmosphere environment where a first superconducting film is located from a first temperature to a second temperature, so that the first superconducting film is in a second atmosphere environment, the first superconducting film being a superconducting material deposited on a substrate; continuously introducing hydrogen atoms into the second atmosphere environment and maintaining for a predetermined duration after the second atmosphere environment reaches the second temperature, so that the first superconducting film is in a third atmosphere environment and micro-scale crystal structure defects of the first superconducting film are filled with the hydrogen atoms, the second temperature being configured to maintain a free state of the hydrogen atoms; and cooling the third atmosphere environment from the second temperature to a third temperature less than the first temperature after the predetermined duration to manufacture a second superconducting film.

### CROSS-REFERENCE TO RELATED APPLICATIONS

The present application claims priority to and the benefits of Chinese Patent Application No. 202211329048.8, filed on Oct. 27, 2022, which is incorporated herein by reference in its entirety.

### TECHNICAL FIELD

The present disclosure relates to the field of materials, and more particularly, to a method for manufacturing superconducting films, a superconducting film, a quantum device, and a quantum chip.

### BACKGROUND

The integration level of a quantum circuit significantly affects its application. It is a realistic problem in the field of quantum chips to integrate more quantum components in the same area. In related art, in order to improve the integration level of the quantum circuit, following schemes are proposed: adjusting the thickness of a superconducting film in the circuit, changing chemical compositions of the superconducting film, and adjusting deposition conditions of the superconducting film on a substrate. However, although the above schemes can increase the integration level of the quantum circuit by increasing the kinetic inductance of the superconducting film, the schemes will bring other negative effects on the quantum circuit, such as reducing a quality factor (Q) of the circuit, affecting the chemical ratio of the film, and affecting other basic physical parameters of the film.

### SUMMARY

Embodiments of the present disclosure provide a method for manufacturing superconducting films, a superconducting film, a quantum device, and a quantum chip.

In some embodiments, a method for manufacturing superconducting films is provided. The method includes: heating a first atmosphere environment where a first superconducting film is located from a first temperature to a second temperature, so that the first superconducting film is in a second atmosphere environment, the first superconducting film being a superconducting material deposited on a substrate; continuously introducing hydrogen atoms into the second atmosphere environment and maintaining for a predetermined duration after the second atmosphere environment reaches the second temperature, so that the first superconducting film is in a third atmosphere environment and micro-scale crystal structure defects of the first superconducting film are filled with the hydrogen atoms, the second temperature being configured to maintain a free state of the hydrogen atoms; and cooling the third atmosphere environment from the second temperature to a third temperature after the predetermined duration, and manufacturing a second superconducting film, the third temperature being less than the first temperature.

In some embodiments, a superconducting film is further provided. The superconducting film is manufactured by using any one of the above methods.

In some embodiments, a microwave component is further provided. The microwave component includes: a substrate and the above superconducting film, the superconducting film being deposited on the substrate.

In some embodiments, a quantum device is further provided. The quantum device includes the above superconducting film.

In some embodiments, a quantum circuit is further provided. The quantum circuit includes the above quantum device.

In some embodiments, a quantum chip is further provided. The quantum chip includes the above quantum device.

In some embodiments, a quantum computer is further provided. The quantum computer includes a quantum memory and the above quantum chip.

In some embodiments, an apparatus is further provided. The apparatus includes a substrate a superconducting film comprising a superconducting material deposited on the substrate. Micro-scale crystal structure defects of the superconducting film are filled with hydrogen atoms. The superconducting film is manufactured by heating an atmosphere environment from a first temperature to a second temperature, continuously introducing hydrogen atoms into the atmosphere environment and maintaining for a predetermined duration after the second temperature for maintaining a free state of the hydrogen atoms is reached, and cooling the atmosphere environment from the second temperature to a third temperature after the predetermined duration, the third temperature being less than the first temperature.

### BRIEF DESCRIPTION OF THE DRAWINGS

The accompanying drawings described herein are intended to provide a further understanding of the present disclosure and constitute a part of this application. Exemplary embodiments of the present disclosure and the description thereof are intended to explain the present disclosure rather than constituting improper limitations to the present disclosure.

FIG. 1 is a flowchart of a method for manufacturing superconducting films, according to some embodiments of the present disclosure.

FIG. 2 is a schematic diagram of a method for manufacturing superconducting films by introducing ammonia, according to some embodiments of the present disclosure.

FIG. 3A and FIG. 3B are schematic diagrams of a low-temperature measurement result of a photoelectron spectrum, according to some embodiments of the present disclosure.

### DETAILED DESCRIPTION

To make a person skilled in the art understand the solutions in the present disclosure better, the following describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art without involving any inventive effort based on the embodiments of the present disclosure shall fall within the protection scope of the present disclosure.

It is to be noted that the terms such as “first” and “second” in this specification, the claims, and the above drawings of the present disclosure are intended to distinguish between similar objects rather than describe a particular sequence or a chronological order. It is to be understood that data used in this way is exchangeable in a proper case, so that the embodiments of the present disclosure described herein can be implemented in an order different from the order shown or described herein. Moreover, the terms “include”, “contain” and any other variants mean to cover the non-exclusive inclusion, for example, a process, method, system, product, or device that includes a list of steps or units is not necessarily limited to those expressly listed steps or units, but may include other steps or units not expressly listed or inherent to such a process, method, system, product, or device.

Embodiments of the present disclosure provide a method for manufacturing superconducting films, a superconducting film, a quantum device, and a quantum chip, to at least solve the technical problem that the kinetic inductance of a superconducting film adopted in a quantum circuit is not high enough.

In embodiments of the present disclosure, a first superconducting film is placed in an atmosphere environment filled with free hydrogen atoms at a second temperature, and micro-scale crystal structure defects of the first superconducting film are filled with the hydrogen atoms, so that the purpose of manufacturing a second superconducting film with significantly improved kinetic inductance without introducing other chemical ingredients is achieved, thereby achieving the technical effect of increasing the kinetic inductance of a superconducting film adopted in a quantum circuit, and further solving the technical problem that the kinetic inductance of the superconducting film adopted in the quantum circuit is not high enough.

According to some embodiments of the present disclosure, a method for manufacturing superconducting films is provided. It is to be noted that the steps shown in the flowcharts of the drawings may be performed in a computer system, such as a set of computer-executable instructions, and that, although a logical order is shown in the flowcharts, the steps shown or described may be performed in an order other than that described herein in some cases.

In order to greatly increase the circuit density under the same circuit size to improve the integration level of a superconducting quantum device (such as a microwave waveguide, a superconducting quantum chip, and a superconducting parametric amplifier), a method of adjusting a kinetic inductance of a superconducting film may be adopted. Kinetic inductance is a manifestation of inertial mass of mobile charge carriers in alternating current electric fields as an equivalent series inductance. From the first formula: ω₀=\sqrt{1/LC}, it can be seen that a frequency ω₀ of the superconducting quantum device is determined by an inductance L and a capacitance C of the superconducting film. From the second formula: L=Lₖ+L_{g}, it can be seen that the inductance L of the superconducting film is determined by a kinetic inductance Lₖ and a geometric inductance L_{g}. Geometric inductance is an inductance caused by the geometric shape and size of quantum devices. With the increase of the integration level of the superconducting quantum circuit, the size of the quantum device is reduced, and the geometric inductance L_{g} thereof will be reduced. Therefore, in order to improve the integration level of the quantum circuit and increase the density of quantum devices per unit circuit area, the kinetic inductance of the material of the superconducting film can be improved while keeping the frequency ω₀ of the superconducting quantum device.

However, the methods of adjusting the kinetic inductance of the material of the superconducting film proposed in the related art will have negative effects. For example, a quality factor Q of the microwave waveguide cannot be maintained. The quality factor Q is a dimensionless parameter representing the damping properties of oscillators, and may directly affect the performance of the microwave waveguide. Furthermore, from the third formula: T=Q/ω_{q}, it can be seen that a lifetime T of a superconducting qubit is directly affected by the quality factor Q of the quantum circuit. Therefore, how to improve the kinetic inductance of the material of the superconducting film without affecting the quality factor Q of the quantum circuit has become an urgent problem to be solved.

In the current quantum competition, it is important to integrate more qubits on chips of the same size and reduce the area of microwave waveguide lines. The present disclosure provides a post-processing method for adjusting the kinetic inductance of nitrogen-based superconducting materials, which can improve the kinetic inductance of the materials without affecting the quality factor of superconductors, thereby effectively increasing the circuit density and providing a feasible solution for large-scale integrated quantum devices.

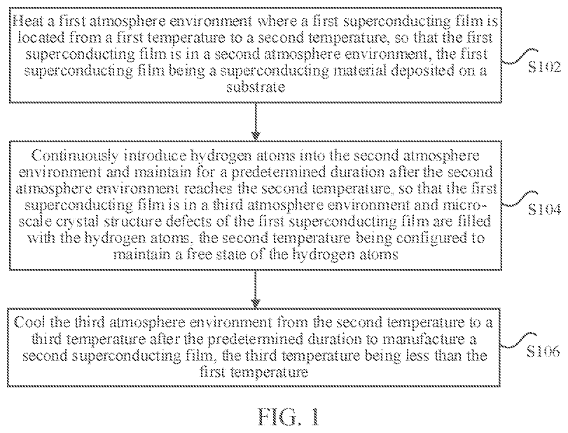

Embodiments of the present disclosure provide a method for manufacturing superconducting films as shown in FIG. 1. FIG. 1 is a flowchart of a method for manufacturing superconducting films, according to some embodiments of the present disclosure. As shown in FIG. 1, the method includes the following steps S102, S104 and S106.

In step S102, a first atmosphere environment where a first superconducting film is located is heated from a first temperature to a second temperature, so that the first superconducting film is in a second atmosphere environment, the first superconducting film being a superconducting material deposited on a substrate.

In this step, the first superconducting film is a superconducting material with epitaxial quality deposited on the substrate at the first temperature. Optionally, the substrate may be a sapphire wafer. The method for manufacturing superconducting films according to some embodiments may be implemented in a low-pressure chemical vapor deposition (LPCVD) furnace. An atmosphere provided by the LPCVD furnace for the superconducting film at different times and under different conditions is the first atmosphere environment or the second atmosphere environment where the first superconducting film is located in step S102 and a third atmosphere environment involved in subsequent steps.

Optionally, a first noble gas may be continuously introduced into the first atmosphere environment as the first atmosphere environment where the first superconducting film is located from the first temperature to the second temperature, and the first atmosphere environment may be heated from the first temperature to the second temperature in a case where the first noble gas is continuously introduced, so as to obtain the second atmosphere environment having the second temperature and filled with the noble gas. The first noble gas may be any one of high-purity nitrogen, helium, argon, or a similar gas that does not interact with the superconducting film. After the atmosphere environment in the LPCVD furnace is filled with the high-purity first noble gas, the first noble gas is continuously introduced into the LPCVD furnace, and the internal temperature of the LPCVD furnace is increased from the first temperature to the second temperature. It is noted that the flow velocity of the first noble gas introduced into the LPCVD furnace may be kept to be equal to or greater than 3000 sccm, so as to ensure that the atmosphere environment is filled with noble gases, to keep the overall chemical properties of the atmosphere environment inactive, and avoid introducing impurities into the superconducting film.

In step S104, hydrogen atoms are continuously introduced into the second atmosphere environment and maintained for a predetermined duration after the second atmosphere environment reaches the second temperature, so that the first superconducting film is in a third atmosphere environment and micro-scale crystal structure defects of the first superconducting film are filled with the hydrogen atoms, the second temperature being configured to maintain a free state of the hydrogen atoms.

Step S104 is a key step in the method for manufacturing superconducting films according to some embodiments. By maintaining the atmosphere of the free hydrogen atoms in the third atmosphere environment for the predetermined duration, the hydrogen atoms and nitrogen atoms may be diffused into the micro-scale crystal structure defects in the superconducting film, and the micro-scale crystal structure defects of the superconducting film may be uniformly filled, so that the kinetic inductance of the superconducting film can be significantly improved. Therefore, the device size can be significantly reduced in a quantum circuit or quantum chip manufactured from the superconducting film processed by the method, and the circuit integration level can be significantly improved.

It is noted that in the process adopted in some embodiments of the present disclosure and other optional embodiments, a key step is to control the participation of the hydrogen atoms in filling the micro-scale crystal structure defects in the first superconducting film. The micro-scale crystal structure defects in the superconducting material are atomic or chemical bond scale defects in the material. Specific structure defect types may include, for example, lattice vacancies, hole defects, or isolated bond defects. In this step, by controlling intrinsic elements in the film to fill such defects, the film density per unit volume can be increased, and the internal gap of a superconducting metal film can be reduced. Because the scattering of Cooper pairs is forbidden when energy is lower than the gap energy of superconducting metal and the Cooper pairs are bosons, the kinetic inductance of the superconducting film can be effectively increased.

Also, the first superconducting film is a superconducting material, and the introduction of the hydrogen atoms into the film does not change the chemical compositions of the superconducting film. Therefore, it can avoid affecting other basic physical parameters of the superconducting film, and avoid reducing the quality factor Q of the superconducting film. With the processing in step S104, the quality factor Q of the superconducting film adopting the superconducting material can even be increased to a certain extent, so that the method for manufacturing superconducting film has a greater application value.

Furthermore, in order to maintain the free state of the hydrogen atoms in the atmosphere environment and ensure that the hydrogen atoms do not combine with other atoms in the atmosphere in large quantities, the second temperature is configured to be a temperature at which the hydrogen atoms do not react in the direction of forming chemical bonds. That is, the hydrogen atoms may freely diffuse without being bound at the second temperature.

It is noted that the above process may be described as “passivation” of the superconducting film. However, a person skilled in the art may understand that referring the phenomenon of filling the micro-scale crystal structure defects of the nitrogen-based superconducting material with the hydrogen atoms to “passivation” is merely a convenient expression for understanding and communicating, and does not mean that the surface of the superconducting film manufactured by the manufacturing method has a macro-scale passivation phenomenon, namely a passivation phenomenon corresponding to the conventional material surface being inactive due to oxidation.

In some optional embodiments, the hydrogen atoms may be continuously introduced into the second atmosphere environment by: continuously introducing a hydrogen-containing gas into the second atmosphere environment, so that the hydrogen-containing gas is cracked into the free hydrogen atoms at the second temperature and the micro-scale crystal structure defects of the first superconducting film are filled with the hydrogen atoms, the second temperature being equal to or greater than a cracking temperature of the hydrogen-containing gas. Optionally, chemical element types of the first superconducting film include chemical element types of the hydrogen-containing gas.

In the above optional embodiments, the hydrogen-containing gas introduced into the atmosphere environment may have the properties that chemical elements included in the hydrogen-containing gas are intrinsic chemical elements of the first superconducting film. That is, in the process of diffusing one or more free atoms, which are generated after the hydrogen-containing gas is cracked, into the micro-scale crystal structure defects of the first superconducting film, impurity atoms will not be introduced into the first superconducting film, so as to avoid the changes of physical properties caused by the introduction of the impurity atoms in the manufactured second superconducting film.

Optionally, in order to ensure the stability of the atmosphere environment and ensure the sufficient, comprehensive, and uniform “passivation” of the superconducting film, the flow velocity of the hydrogen-containing gas including ammonia continuously introduced into the atmosphere environment may be set to be equal to or greater than 50 sccm. The predetermined duration for processing the first superconducting film may be set to be equal to or greater than 600 seconds, so as to ensure that the kinetic inductance of the superconducting film can be significantly improved.

In step S106, the third atmosphere environment is cooled from the second temperature to a third temperature after the predetermined duration to manufacture a second superconducting film, the third temperature being less than the first temperature.

The second superconducting film is a manufactured product with significantly improved kinetic inductance as compared to the first superconducting film, and the quality factor Q of the second superconducting film is not significantly reduced as compared to the first superconducting film. Therefore, the size of the quantum circuit can be reduced without affecting the quality of the quantum circuit, thereby increasing the circuit integration level in the quantum chip.

It is noted that the third temperature is required to be less than the first temperature in the cooling process, so as to avoid the superconducting film with the filled micro-scale crystal structure defects reacting with atmosphere gas in the atmosphere environment at the third temperature, so that the manufactured second superconducting film has higher purity and better performance. If the third temperature is not ensured to be less than the first temperature, additional by-products may be produced in the film during cooling, and the physical properties of the film will be changed, leading to a failure to achieve the purpose of manufacturing a high-purity superconducting film with the increased kinetic inductance.

In some optional embodiments, as the third atmosphere environment is cooled from the second temperature to the third temperature, a second noble gas may be continuously introduced into the third atmosphere environment in a manner similar to that adopted during heating, and the third atmosphere environment may be cooled from the second temperature to the third temperature in a case where the second noble gas is continuously introduced. Optionally, the second noble gas may be any one of high-purity nitrogen, helium, argon, or a similar gas that does not interact with the superconducting film. The second noble gas may be the same as the first noble gas or may be different from the first noble gas. When the atmosphere environment in the LPCVD furnace is filled with the high-purity second noble gas, the cooling action is started to reduce the second temperature to the third temperature, and the second noble gas is continuously introduced into the LPCVD furnace during cooling, so as to keep the chemical properties of the overall environment inactive and avoid introducing impurities into the superconducting film.

In some optional embodiments, the process of manufacturing the superconducting film with improved kinetic inductance may be carried out in a reaction tube of the LPCVD. The first noble gas and the second noble gas may be pre-stored in a high-purity gas cylinder. When the first noble gas or the second noble gas is introduced into the atmosphere environment, the first noble gas and the second noble gas may be introduced into the reaction tube through a gas path provided by the LPCVD. Optionally, when the first noble gas and the second noble gas are nitrogen or argon, the purity of the noble gas may be controlled to be above 99.999%. When the hydrogen-containing gas supplied to the reaction tube is ammonia, the purity of the ammonia may be controlled to be above 99.9999%, so as to ensure that only hydrogen atoms and nitrogen atoms are introduced into the manufactured second superconducting film as compared to the first superconducting film while no other impurities are introduced, thereby ensuring that the kinetic inductance of the manufactured second superconducting film is significantly improved as compared to the first superconducting film and other physical properties of the film are not changed.

When the temperature of the third atmosphere environment is reduced to the third temperature, the manufacturing process is completed, and the second superconducting film with significantly improved kinetic inductance is obtained.

Through the above steps, a first superconducting film is placed in an atmosphere environment filled with free hydrogen atoms at a second temperature, and micro-scale crystal structure defects of the first superconducting film are filled with the hydrogen atoms, so that the purpose of manufacturing a second superconducting film with significantly improved kinetic inductance without introducing other chemical ingredients is achieved, thereby achieving the technical effect of increasing the kinetic inductance of a superconducting film adopted in a quantum circuit, and further solving the technical problem that the kinetic inductance of the superconducting film adopted in the quantum circuit is not high enough.

In some optional embodiments, the superconducting material adopted in the first superconducting film may be a nitrogen-based superconducting material, a phosphorus-based superconducting material, or a metal-rich carbide superconducting material. In order to ensure that impurities are not introduced into the superconducting material in the process of filling the micro-scale crystal structure defects of the first superconducting film, the selection of the hydrogen-containing gas for cracking the hydrogen atoms may follow the principle that the chemical element types of the hydrogen-containing gas do not exceed the chemical element types of the superconducting material of the first superconducting film.

Optionally, when the superconducting material of the first superconducting film is a nitrogen-based superconducting material, a nitrogen-hydrogen compound gas containing only two chemical elements of hydrogen and nitrogen, such as ammonia (NH 3), may be selected as the hydrogen-containing gas, and when the ammonia is selected as the hydrogen-containing gas, the second temperature is required to be equal to or greater than 400° C. considering that the ammonia will crack out free hydrogen atoms and nitrogen atoms at a temperature of 400° C. or above.

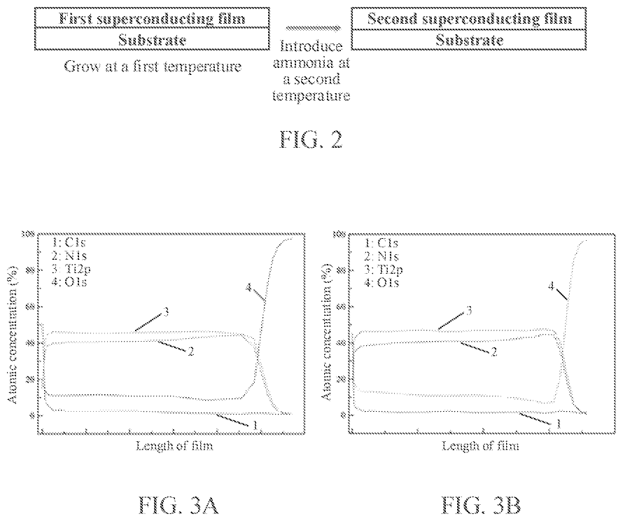

FIG. 2 is a schematic diagram of a method for manufacturing superconducting films by introducing ammonia, according to some embodiments of the present disclosure. A person skilled in the art may understand that the ammonia may be cracked into hydrogen atoms and nitrogen atoms at an environment temperature of 400° C. Therefore, when the second temperature is equal to or greater than 400° C., the ammonia slowly introduced into the LPCVD furnace may be cracked into free hydrogen atoms and nitrogen atoms at a higher temperature and filled in the atmosphere environment, so that the hydrogen atoms and the nitrogen atoms gradually diffuse into the micro-scale crystal structure defects of the first superconducting film to achieve the purpose of changing the kinetic inductance of the superconducting film.

In some optional embodiments, the nitrogen-based superconducting material may include any of the following: titanium nitride, aluminum nitride, and gallium nitride. It is appreciated that the method for manufacturing superconducting films according to the above embodiments is equally effective for other nitrides with superconducting properties.

Optionally, when the superconducting material of the first superconducting film is a phosphorus-based superconducting material, a phosphorus-hydrogen compound gas containing only two chemical elements of hydrogen and phosphorus, such as phosphine (PH₃), is selected as the hydrogen-containing gas, and when the phosphine is selected as the hydrogen-containing gas, the second temperature is required to be a temperature at which free hydrogen atoms may be cracked out of the phosphine in consideration of the chemical properties of the phosphine. For example, if the phosphine will be cracked into free hydrogen atoms and phosphorus atoms at a temperature of 500° C. or above under a physical environment for manufacturing the second superconducting film, the second temperature may be set to be equal to or greater than 500° C.

Optionally, when the superconducting material of the first superconducting film is a metal-rich carbide superconducting material, a hydrocarbon gas containing only two chemical elements of hydrogen and carbon, such as methane and acetylene, may be selected as the hydrogen-containing gas. Optionally, the metal-rich carbide superconducting material may be WRe₂C or MoRe₂C.

Table 1 shows changes in physical parameters of a titanium nitride superconducting film before and after being processed by using a method for manufacturing superconducting films according to some embodiments of the present disclosure. The first superconducting film is a superconducting film before being “passivated” by the method for manufacturing superconducting films, and the second superconducting film is a superconducting film after being “passivated” by the method for manufacturing superconducting films. Rs shown in Table 1 is the surface resistance of the material. The surface resistance is a physical quantity obtained by dividing resistivity p by the thickness of the material. As shown in Table 1, Rs of the superconducting film after being processed by the above manufacturing method is increased by an average of 37%, and the overall uniformity of the superconducting film is also increased. From the following formula: Lₖ=\sqrt{ℏRₛ/πΔ}, it can be seen that as Rₛ of the superconducting film is increased by 37%, the kinetic inductance of the superconducting film can be significantly improved by 17%, and the overall uniformity of the film will not be affected.

TABLE 1

| | Rs(ohms per | | Rs(ohms per |
|---|---|---|---|
| | square) | Uniformity | square) |
| First superconducting film | 11.6 ± 0.451 | +/−5.9% | about 11.6 |
| Second superconducting film | 15.9 ± 0.857 | +/−8.4% | about 15.9 |

Furthermore, Table 2 shows changes in a quality factor Q of a resonator manufactured from a titanium nitride superconducting film before and after being processed by using a method for manufacturing superconducting films according to some embodiments of the present disclosure. Qᵢ shown in Table 2 represents the internal quality factor of the circuit, Qᵢ is a dimensionless physical quantity, and the reciprocal 1/Qᵢ thereof may be used for directly quantifying the loss of the circuit. In Table 2, high-power Qᵢ and low-power Qᵢ correspond to the power of microwave input respectively. Generally, the input of high-power is greater than 10 db, and the input of low-power is −40 db. From Table 2, it can be seen that the quality factor Q of the second superconducting film manufactured by using the method for manufacturing superconducting films according to the above embodiments and the optional embodiments is not reduced, but is greatly improved in some cases. Therefore, the film has a good market application prospect.

TABLE 2

| | | | Resonator |
|---|---|---|---|
| | Qᵢ | Qᵢ | frequency |
| | (low-power) | (high-power) | (MHz) |
| First superconducting film | about 658k | about 2873k | 5002 |
| Second superconducting film | about 759k | about 6742k | 4888 |

FIG. 3A and FIG. 3B are schematic diagrams of a low-temperature measurement result of a photoelectron spectrum according to some embodiments of the present disclosure. As shown in FIG. 3A and FIG. 3B, the ordinate is the percentage of material atoms and the abscissa is the time of detection using a photoelectron spectrometer. FIG. 3A is a detection result of a superconducting film after being processed by using the method for manufacturing superconducting films, namely, the depth distribution of element concentration in a superconducting film sample after reaction. FIG. 3B is a detection result of a superconducting film before being processed by using the method for manufacturing superconducting films, namely, the depth distribution of element concentration in a superconducting film sample before reaction. It is clear that before and after processing, the distribution trend of atomic concentration with depth is consistent from the relationship between the concentration of main elements of the superconducting film and the depth of the film. Therefore, the proportion of nitrogen, oxygen, and titanium in the superconducting film does not change significantly, and the chemical compositions of the superconducting film before and after being processed are very stable.

The above embodiments and the optional embodiments provide an effective post-processing method for superconducting films, which “passivates” a nitrogen-based superconducting film, thereby improving the kinetic inductance of materials without affecting the subsequent process. In addition, it is not found that the quality factor Q of a superconducting resonator is affected under the test of a microwave frequency domain, thus providing an effective way to regulate and control the kinetic inductance of the materials and being an effective solution for increasing the circuit density.

It is to be noted that while the foregoing method embodiments have been described in terms of various combinations of actions for brevity, a person skilled in the art will recognize that the present disclosure is not limited by the described order of actions, as some steps may, in accordance with the present disclosure, be performed in other orders or simultaneously. Furthermore, a person skilled in the art will also recognize that the embodiments described in this specification belong to exemplary embodiments and that the actions and modules involved are not necessarily required of the present disclosure.

The present disclosure further provides a superconducting film manufactured by using the method for manufacturing superconducting films and a microwave component. The microwave component may be a microwave waveguide or a microwave resonator. The microwave component includes a superconducting film grown on a substrate. The substrate may be a sapphire wafer. The superconducting film is a superconducting film manufactured by using any of the above embodiments or optional embodiments.

The present disclosure further provides a quantum device manufactured from the superconducting film, a quantum circuit and a quantum chip adopting the quantum device, and a quantum computer including a quantum memory and the quantum chip. A person skilled in the art may understand that the size of the quantum device can be reduced by the superconducting film with significantly improved kinetic inductance, thereby improving the integration level of the quantum circuit and the quantum chip, and greatly improving the circuit complexity per unit area.

Optionally, the quantum device may include a Fluxonium qubit, or the quantum device may also include a Transmon qubit. The Fluxonium qubit and the Transmon qubit are quantum devices manufactured from the superconducting film according to any of the above embodiments or optional embodiments of the present disclosure.

The sequence numbers of the embodiments of the present disclosure are merely for the description purpose but do not imply the preference among the embodiments.

In the above embodiments of the present disclosure, the descriptions of the embodiments have different focuses. For a part that is not detailed in some embodiments, reference may be made to the relevant description of other embodiments.

In the several embodiments provided in the present disclosure, it is to be understood that the disclosed technical content may be implemented in other manners. The above embodiments may also be implemented in conjunction with an apparatus for executing program code. The division of units included in the apparatus is only a logical function division. In actual implementation, there may be another division mode. For example, a plurality of units or components may be combined or integrated into another system, or some features may be ignored or not executed. In addition, the coupling, or direct coupling, or communication connection between the displayed or discussed components may be the indirect coupling or communication connection by means of some interfaces, units, or modules, and may be electrical or of other forms.

The units described as separate components may or may not be physically separated, and the components displayed as units may or may not be physical units, and may be located in one place or may be distributed over a plurality of network units. Some or all of the units may be selected according to actual needs to achieve the objectives of the solutions of the embodiments.

In addition, functional units in the embodiments of the present disclosure may be integrated into one processing unit, or each of the units may be physically separated, or two or more units may be integrated into one unit. The integrated unit may be implemented in the form of hardware, or may be implemented in a form of a software functional unit.

When the integrated unit is implemented in the form of a software functional unit and sold or used as an independent product, the integrated unit may be stored in a computer-readable storage medium. Based on such an understanding, the technical solutions of the present disclosure essentially, or the part contributing to the prior art, or all or some of the technical solutions may be presented in the form of a software product. The computer software product is stored in the storage medium, and includes several instructions for instructing one or more computer devices (which may be a personal computer, a server, a network device, or the like) to perform all or some of the steps of the methods described in the embodiments of the present disclosure. The foregoing storage medium includes: various media such as a USB flash drive, a read-only memory (ROM), a random access memory (RAM), a removable hard disk, a magnetic disk, and an optical disc that may store the program code.

The embodiments may further be described using the following clauses:
1: A method for manufacturing superconducting films, comprising: heating a first atmosphere environment where a first superconducting film is located from a first temperature to a second temperature, so that the first superconducting film is in a second atmosphere environment, the first superconducting film being a superconducting material deposited on a substrate; continuously introducing hydrogen atoms into the second atmosphere environment and maintaining for a predetermined duration after the second atmosphere environment reaches the second temperature, so that the first superconducting film is in a third atmosphere environment and micro-scale crystal structure defects of the first superconducting film are filled with the hydrogen atoms, the second temperature being configured to maintain a free state of the hydrogen atoms; and cooling the third atmosphere environment from the second temperature to a third temperature after the predetermined duration to manufacture a second superconducting film, the third temperature being less than the first temperature.
2: The method as paragraph 1 describes, wherein continuously introducing hydrogen atoms into the second atmosphere environment and maintaining for the predetermined duration comprises: continuously introducing a hydrogen-containing gas into the second atmosphere environment, so that the hydrogen-containing gas is cracked into free hydrogen atoms at the second temperature and the micro-scale crystal structure defects of the first superconducting film are filled with the hydrogen atoms, the second temperature being equal to or greater than a cracking temperature of the hydrogen-containing gas.
3: The method as either of paragraphs 1 or 2 describe, wherein chemical element types of the first superconducting film comprise chemical element types of the hydrogen-containing gas.
4: The method as any of paragraphs 1-3 describe, wherein the first superconducting film comprises a nitrogen-based superconducting material.
5: The method as any of paragraphs 1-4 describe, wherein the nitrogen-based superconducting material comprises any of the following: titanium nitride, aluminum nitride, or gallium nitride.
6: The method as any of paragraphs 1-5 describe, wherein the hydrogen-containing gas comprises: a nitrogen-hydrogen compound.
7: The method as any of paragraphs 1-6 describe, wherein the nitrogen-hydrogen compound comprises ammonia, and the second temperature is equal to or greater than 400° C.
8: The method as any of paragraphs 1-7 describe, wherein the first superconducting film comprises a phosphorus-based superconducting material.
9: The method as any of paragraphs 1-8 describe, wherein the hydrogen-containing gas comprises: a phosphorus-hydrogen compound.
10: The method as any of paragraphs 1-9 describe, wherein the phosphorus-hydrogen compound comprises PH₃, and the second temperature is equal to or greater than 500° C.
11: The method as any of paragraphs 1-10 describe, wherein a flow velocity of the hydrogen-containing gas continuously introduced into the second atmosphere environment is equal to or greater than 50 sccm.
12: The method as any of paragraphs 1-11 describe, wherein the predetermined duration is equal to or greater than 600 seconds.
13: The method as any of paragraphs 1-12 describe, wherein heating the first atmosphere environment where the first superconducting film is located from the first temperature to the second temperature comprises: continuously introducing a first noble gas into the first atmosphere environment, and heating the first atmosphere environment from the first temperature to the second temperature in a case where the first noble gas is continuously introduced; and wherein cooling the third atmosphere environment from the second temperature to the third temperature comprises: continuously introducing a second noble gas into the third atmosphere environment, and cooling the third atmosphere environment from the second temperature to the third temperature in a case where the second noble gas is continuously introduced.
14: The method as any of paragraphs 1-13 describe, wherein a flow velocity of the first noble gas continuously introduced into the first atmosphere environment is equal to or greater than 3000 sccm, and a flow velocity of the second noble gas continuously introduced into the third atmosphere environment is equal to or greater than 3000 sccm.
15: A superconducting film, the superconducting film being manufactured by using the method for manufacturing superconducting films according to as any of paragraphs 1-14 describe.
16: A microwave component, comprising: a substrate and a superconducting film of paragraph 15, the superconducting film being deposited on the substrate.
17: A quantum device, comprising a superconducting film of paragraph 15.
18: The quantum device as paragraph 17 describes, further comprising: a Fluxonium qubit manufactured from the superconducting film.
19. The quantum device as paragraph 17 or 18 describes, further comprising: a Transmon qubit manufactured from the superconducting film.
20. A quantum circuit, comprising a quantum device of any of paragraphs 17-19.
21: A quantum chip, comprising a quantum device of any of paragraphs 17-19.
22. A quantum computer, comprising: a quantum memory and a quantum chip of claim 21.
23: An apparatus, comprising: a substrate; and a superconducting film comprising a superconducting material deposited on the substrate; wherein micro-scale crystal structure defects of the superconducting film are filled with hydrogen atoms; wherein the superconducting film is manufactured by heating an atmosphere environment from a first temperature to a second temperature, continuously introducing hydrogen atoms into the atmosphere environment and maintaining for a predetermined duration after the second temperature for maintaining a free state of the hydrogen atoms is reached, and cooling the atmosphere environment from the second temperature to a third temperature after the predetermined duration, the third temperature being less than the first temperature.
24: The apparatus as paragraph 23 describes, wherein the superconducting film comprises a nitrogen-based superconducting material or a phosphorus-based superconducting material.
25: The apparatus as either of paragraphs 23 or 24 describe, wherein the nitrogen-based superconducting material comprises any of the following: titanium nitride, aluminum nitride, or gallium nitride.
26: The apparatus as any of paragraphs 23-25 describe, further comprising: a microwave component comprising the superconducting film grown on the substrate.
27: The apparatus as any of paragraphs 23-26 describe, further comprising: a quantum device comprising a Fluxonium qubit manufactured from the superconducting film or a Transmon qubit manufactured from the superconducting film.
28: The apparatus as any of paragraphs 23-27 describe, wherein the apparatus is a quantum computer comprising: a quantum memory; and a quantum chip coupled to the quantum memory, the quantum chip comprising the quantum device.

The foregoing descriptions are exemplary implementations of the present disclosure. It is to be noted that a person of ordinary skill in the art may make some improvements and modifications without departing from the principle of the present disclosure and the improvements and modifications shall fall within the protection scope of the present disclosure.

What is claimed is:

1. A method for manufacturing superconducting films, comprising:
heating a first atmosphere environment where a first superconducting film is located from a first temperature to a second temperature, so that the first superconducting film is in a second atmosphere environment, the first superconducting film being a superconducting material deposited on a substrate;
continuously introducing hydrogen atoms into the second atmosphere environment and maintaining for a predetermined duration after the second atmosphere environment reaches the second temperature, so that the first superconducting film is in a third atmosphere environment and micro-scale crystal structure defects of the first superconducting film are filled with the hydrogen atoms, the second temperature being configured to maintain a free state of the hydrogen atoms; and
cooling the third atmosphere environment from the second temperature to a third temperature after the predetermined duration to manufacture a second superconducting film, the third temperature being less than the first temperature.

2. The method of claim 1, wherein continuously introducing hydrogen atoms into the second atmosphere environment and maintaining for the predetermined duration comprises:
continuously introducing a hydrogen-containing gas into the second atmosphere environment, so that the hydrogen-containing gas is cracked into free hydrogen atoms at the second temperature and the micro-scale crystal structure defects of the first superconducting film are filled with the hydrogen atoms, the second temperature being equal to or greater than a cracking temperature of the hydrogen-containing gas.

3. The method of claim 2, wherein chemical element types of the first superconducting film comprise chemical element types of the hydrogen-containing gas.

4. The method of claim 2, wherein the first superconducting film comprises a nitrogen-based superconducting material.

5. The method of claim 4, wherein the nitrogen-based superconducting material comprises any of the following: titanium nitride, aluminum nitride, or gallium nitride.

6. The method of claim 4, wherein the hydrogen-containing gas comprises: a nitrogen-hydrogen compound.

7. The method of claim 6, wherein the nitrogen-hydrogen compound comprises ammonia, and the second temperature is equal to or greater than 400° C.

8. The method of claim 2, wherein the first superconducting film comprises a phosphorus-based superconducting material.

9. The method of claim 8, wherein the hydrogen-containing gas comprises: a phosphorus-hydrogen compound.

10. The method of claim 9, wherein the phosphorus-hydrogen compound comprises PH₃, and the second temperature is equal to or greater than 500° C.

11. The method of claim 2, wherein a flow velocity of the hydrogen-containing gas continuously introduced into the second atmosphere environment is equal to or greater than 50 sccm.

12. The method of claim 11, wherein the predetermined duration is equal to or greater than 600 seconds.

13. The method of claim 1, wherein heating the first atmosphere environment where the first superconducting film is located from the first temperature to the second temperature comprises:
continuously introducing a first noble gas into the first atmosphere environment, and heating the first atmosphere environment from the first temperature to the second temperature in a case where the first noble gas is continuously introduced; and
wherein cooling the third atmosphere environment from the second temperature to the third temperature comprises:
continuously introducing a second noble gas into the third atmosphere environment, and cooling the third atmosphere environment from the second temperature to the third temperature in a case where the second noble gas is continuously introduced.

14. The method of claim 13, wherein a flow velocity of the first noble gas continuously introduced into the first atmosphere environment is equal to or greater than 3000 sccm, and a flow velocity of the second noble gas continuously introduced into the third atmosphere environment is equal to or greater than 3000 sccm.

15. An apparatus, comprising:
a substrate; and
a superconducting film comprising a superconducting material deposited on the substrate;
wherein micro-scale crystal structure defects of the superconducting film are filled with hydrogen atoms;
wherein the superconducting film is manufactured by heating an atmosphere environment from a first temperature to a second temperature, continuously introducing hydrogen atoms into the atmosphere environment and maintaining for a predetermined duration after the second temperature for maintaining a free state of the hydrogen atoms is reached, and cooling the atmosphere environment from the second temperature to a third temperature after the predetermined duration, the third temperature being less than the first temperature.

16. The apparatus of claim 15, wherein the superconducting film comprises a nitrogen-based superconducting material or a phosphorus-based superconducting material.

17. The apparatus of claim 15, wherein the nitrogen-based superconducting material comprises any of the following: titanium nitride, aluminum nitride, or gallium nitride.

18. The apparatus of claim 15, further comprising:
a microwave component comprising the superconducting film grown on the substrate.

19. The apparatus of claim 15, further comprising:
a quantum device comprising a Fluxonium qubit manufactured from the superconducting film or a Transmon qubit manufactured from the superconducting film.

20. The apparatus of claim 19, wherein the apparatus is a quantum computer comprising:
a quantum memory; and
a quantum chip coupled to the quantum memory, the quantum chip comprising the quantum device.
